(19) United States
(12) Patent Application Publication
(10) Pub. No.: US 2008/0315401 A1
(43) Pub. Date: Dec. 25, 2008

(54) Power Semiconductor Module And Method of Manufacturing the Power Semiconductor Module

(75) Inventors: Hisayuki Imamura, Fukaya (JP); Toshiaki Morita, Hitachi (JP); Hiroshi Houzouji, Hitachiota (JP)

Correspondence Address: CROWELL & MORING LLP;INTELLECTUAL PROPERTY GROUP, P.O. BOX 14300, WASHINGTON, DC, 20044-4300, US

(73) Assignee: Hitachi, Ltd., Tokyo (JP)

(21) Appl. No.: 12/141,670

(22) Filed: Jun. 18, 2008

(30) Foreign Application Priority Data
Jun. 25, 2007 (JP) 2007-165748

(51) Int. Cl. H01L 23/36; H01L 21/58

(52) U.S. Cl. 257/712; 438/122; 257/E23.101; 257/E21.505

(57) ABSTRACT

A power semiconductor module has a silicon nitride insulated substrate, a metal circuit plate made of Cu or a Cu alloy, which is disposed on one surface of the silicon nitride insulated substrate, a semiconductor chip mounted on the metal circuit plate, and a heat dissipating plate made of Cu or a Cu alloy, which is disposed on the other surface of the silicon nitride insulated substrate; a carbon fiber-metal composite made of carbon fiber and Cu or a Cu alloy is provided between the silicon nitride insulated substrate and the metal circuit plate; the thermal conductivity of the carbon fiber-metal composite in a direction in which carbon fiber of the carbon fiber-metal composite is oriented is 400 W/m·k or more. Accordingly, a power semiconductor module that has a low thermal resistance between the semiconductor chip and a heat dissipating mechanism and also has improved cooling capacity is provided.

### CLAIM OF PRIORITY

The present application claims priority from Japanese patent application serial No. 2007-165748, filed on Jun. 25, 2007, the content of which is hereby incorporated by reference into this application.

### FIELD OF THE INVENTION

The present invention relates to a power semiconductor module and a method of manufacturing the power semiconductor module.

### BACKGROUND OF THE INVENTION

Semiconductor devices, particularly power semiconductor devices that control switching of high current, generate much heat. To ensure that these power semiconductor devices operate stably, cooling structures with superior cooling efficiency have been considered. Performance required to cool a power semiconductor device depends on the environment of the electric system in which the electric circuit module including the power semiconductor module is mounted. For example, an inverter mounted on an automobile requires high cooling performance due to a mounting environment and operation environment.

An exemplary conventional power semiconductor device is disclosed in Patent Document 1, which describes a power semiconductor module using a carbon fiber composite. Since the power semiconductor module is superior in thermal resistance and temperature cycle characteristics and enables heat generation and resistance to be reduced, current to be supplied to the device can be increased 1.5 to 2.0 times and the device size or the number of chips can be reduced, making it possible to reduce the cost of the device.

Patent Document 1: Japanese Patent Laid-open No. 2005-5400

### SUMMARY OF THE INVENTION

Recent electric power converting (inverting) systems in which a power module is mounted are required to be reduced in size and cost and have high reliability. For examples, major problems with automobiles are to reduce the size and cost of an electric power converting system in which a power module is mounted and to increase the reliability of the system. That is, requirements for automobiles are to reduce effects on the earth environment and increase gas mileage. To satisfy these requirements, widespread use of vehicle driving mechanisms or motor pre-driver that electrically operate is essential. Accordingly, ease of mounting an inverter on a vehicle must be improved and the cost of the inverter must be reduced. Major problems with automobiles are then to reduce the size and cost of the inverter and increase its reliability.

Particularly for an electric power converting system in which semiconductor chips that generate heat when current is supplied to them are used to form an electric circuit, an attempt to reduce the chip size results in an increase in the heat capacity of the device. For this reason, to reduce the size and cost of an electric system and stabilize the operation of a power module, that is, increase its reliability, performance to cool the power module must be increased. In view of this, it is required for strong type hybrid electric vehicle (HEV) with a driving motor output of 15 kW or more that the thermal resistance Rj-w of the power module is reduced to 0.15° C./W or less.

For a power semiconductor module described in Patent Document 1, a carbon fiber composite layer is provided between a semiconductor chip and a heat sink, and a metal heat transfer plate is provided between the semiconductor chip and the carbon fiber composite layer to transfer heat generated by the semiconductor chip to an entire surface of the carbon fiber composite layer so that the cooling performance is improved. An intermediate heat sink, which is a copper plate, is also provided between the heat sink and the carbon fiber composite layer as a heat buffer. However, when this type of power semiconductor module is mounted on an HEV, it is problematic in that heat dissipation sufficient as a power module is not achieved. In Patent Document 1, an intermediate heat sink layer comprising a Cu plate is provided between an insulating body made of ceramics and the carbon fiber composite layer. When the heat capacity needs to be increased, the intermediate heat sink layer is effective in reduction of the thermal resistance of the module itself. For a strong type HEV, electric power exceeding 300 V×300 A is supplied to a power module, so heat is stored in the intermediate heat sink layer, increasing the thermal resistance. Accordingly, it is difficult to reduce the thermal resistance Rj-w to 0.15° C./W or less as required for power modules mounted HEVs of the above type.

An object of the present invention is to provide a power semiconductor module cooling performance of which is increased by reducing a thermal resistance between the semiconductor chip and a heat dissipating mechanism as well as an inverter system, an electric power converting system, and a vehicle-mounted electric system in which the power semiconductor module is used to reduce their size and cost and to increase their reliability.

To achieve the above object, the present invention, which is a power semiconductor module, has a silicon nitride insulated substrate, a metal circuit made of Cu or a Cu alloy, which is disposed on one surface of the silicon nitride insulated substrate, a semiconductor chip mounted on the metal circuit board, and a heat dissipating plate made of Cu or a Cu alloy, which is disposed on the other surface of the silicon nitride insulated substrate; a carbon fiber-metal composite made of carbon fiber and Cu or a Cu alloy is provided between the silicon nitride insulated substrate and the metal circuit; the thermal conductivity of the carbon fiber-metal composite in a direction in which carbon fiber of the carbon fiber-metal composite is oriented is 400 W/m·k or more.

To achieve the above object, the metal circuit board and the semiconductor chip are mutually bonded with Ag powder or an Ag sheet bonding material, and the heat conductivity of a resulting bonding layer is 80 W/m·k or more but 400 W/m·k or less.

To achieve the above object, the thickness of the carbon fiber-metal composite is within a range of 0.2 to 5 mm.

To achieve the above object, a surface layer made of Ni or Cu is formed on a surface of the carbon fiber-metal composite, the thickness of which is within a range of 0.5 to 20 μm.

To achieve the above object, the carbon fiber-metal composite and the metal circuit are mutually brazed with an Ag—Cu—In filler metallic brazing material; the carbon-fiber composite and the silicon nitride insulated substrate are mutually brazed with an Ag—Cu—In—Ti filler metallic brazing material; the silicon nitride insulated substrate and the heat dissipating plate is also mutually brazed with an Ag—Cu—In—Ti filler metallic brazing material.

To achieve the above object, a direct cooling mechanism is provided immediately below the heat dissipating plate so as to bring the heat dissipating plate into contact with coolant; the flow rate of the coolant is 5 liters/minute or more but 15 liters/minute or less; the water pressure is within a range of 5 to 50 kPa.

To achieve the above object, an Ag—Cu—In—Ti filler metallic brazing material layer is used for bonding between the carbon fiber-metal composite and the metal circuit board made of Cu or a Cu alloy, which is disposed on the top of the metal circuit board, between the carbon fiber-metal composite and the silicon nitride substrate, which is disposed on the bottom of the carbon fiber-metal composite, and between the silicon nitride substrate and the heat dissipating plate made of Cu or a Cu alloy, which is disposed on the bottom of the silicon nitride substrate; the bonding is carried out simultaneously at a bonding temperature of 600° C. to 750° C.

The structure described above reduces the thermal resistance between the semiconductor chip and the heat dissipating mechanism and thereby improves the cooling performance. It also becomes possible to reduce the sizes and costs of an electric power converting system and a vehicle-mounted electric system and to increase their reliability.

The present invention can provide a power semiconductor module for which cooling performance can be improved by reducing a thermal resistance between a semiconductor chip and a heat dissipating mechanism.

It is also possible to reduce the sizes and costs of an inverter and a vehicle-mounted electric system and to increase their reliability.

### BRIEF DESCRIPTION OF THE DRAWINGS

FIG. 1 is a cross sectional view illustrating the structure of a power semiconductor module according to an embodiment of the present invention.

FIG. 2 is a graph illustrating relationship among the thermal conductivity and thickness of a carbon fiber-metal composite used in the power semiconductor module according to the embodiment of the present invention and the thermal resistance of the power semiconductor module.

FIG. 3 is a graph illustrating relationship between the thermal conductivity of a bonding layer, which is disposed below a semiconductor chip and used in the power semiconductor module according to the embodiment of the present invention, and the thermal resistance of the power semiconductor module.

FIG. 4 is a graph illustrating relationship among the thickness of a surface layer of the carbon fiber composite, which is used in the power semiconductor module according to the embodiment of the present invention, and the thermal resistance and temperature cycle life of the power semiconductor module.

FIG. 5 is a graph illustrating relationship between the thermal conductivity of the carbon fiber composite, which is used in the power semiconductor module according to the embodiment of the present invention, the number of semiconductor chips, and the thermal resistances of the power semiconductor module.

FIG. 6 is a graph illustrating relationship among the size of the semiconductor chip, which is used in the power semiconductor module according to the embodiment of the present invention, the thermal resistance of the power semiconductor module, and the fault rate of the semiconductor chip.

FIG. 7 is a cross sectional view illustrating the structure of a power semiconductor module according to another embodiment of the present invention.

FIG. 8 is a cross sectional view illustrating the structure of a cooling mechanism, which is used in the power semiconductor module according to the other embodiment of the present invention.

FIG. 9 is a block diagram of a hybrid electric vehicle that includes a vehicle-mounted electric system structured by using an inverter INV that embodies the present invention and also has an engine system having an internal engine.

FIG. 10 is a cross sectional view illustrating the structure of a cooling mechanism used in a conventional power semiconductor module.

### DESCRIPTION OF THE PREFERRED EMBODIMENTS

Embodiments of the present invention will be described with reference to the drawings.

In the embodiments described below, a vehicle-mounted inverter, which undergoes severe thermal cycles and operates in a server operation environment, will be used as an example to describe a power semiconductor module according to the present invention and an inverter in which the power semiconductor module is mounted. The vehicle-mounted inverter is disposed in a vehicle-mounted electric system as a controller for controlling the driving of a vehicle-mounted motor. To control the driving of the vehicle-mounted motor, the inverter receives DC electric power from a vehicle-mounted battery, which is a vehicle-mounted power supply, converts the received DC electric power to prescribed AC electric power, and supplies the resulting AC electric power to the vehicle-mounted motor.

The structure described below can also be applied to a power module that constitutes an electric power converting part in a DC-DC inverter such as a DC-DC converter or DC chopper or in an AC-DC inverter.

The structure described below can also be applied to a power module that constitutes an electric power converting part in an inverter mounted in an industrial electric system such as a motor driving system in a factory or in an inverter mounted in a home electric system such as a home photovoltaic power generation system or home motor driving system.

First, a power semiconductor module that embodies the present invention will be described with reference to FIGS. 1 to 6.

FIG. 1 is a cross sectional view illustrating the structure of a power semiconductor module according to a first embodiment of the present invention.

The inventive power semiconductor module comprises a semiconductor chip 1, a metal circuit 2, a carbon fiber-metal composite 5, an insulated substrate (silicon nitride insulated substrate) 7, and a heat dissipating plate 8. The metal circuit 2, which is made of Cu or a Cu alloy, is disposed on one surface of the silicon nitride insulated substrate 7. The semiconductor chip 1 is bonded to the metal circuit 2 through a bonding layer 3 below the semiconductor chip 1. The carbon fiber-metal composite 5 is made of carbon fiber and Cu or a Cu alloy and has a thermal conductivity of 400 W/m·k or more. The carbon fiber-metal composite 5 is disposed between the silicon nitride insulated substrate 7 and the metal circuit 2. The carbon fiber-metal composite 5 and silicon nitride insulated substrate 7 are mutually bonded with a brazing material 4, and the carbon fiber-metal composite 5 and the metal circuit 2 are mutually bonded with another brazing material 4. The heat dissipating plate 8, which is made of Cu or a Cu alloy, is bonded to the other surface of the silicon nitride insulated substrate 7 through another brazing material 4.

An insulated gate bipolar transistor (IGBT), a metal-oxide semiconductor field effect transistor (MOS-FET), or the like can be used as the semiconductor chip 1.

Surface layers 6 are formed on the surfaces of the carbon fiber-metal composite 5 as Ni layers or Cu layers to improve bonding between the carbon fiber-metal composite 5 and the metal circuit board 2 and between the carbon fiber-metal composite 5 and the silicon nitride insulated substrate 7. The thickness of the surface layer 6 is preferably within a range of 0.5 to 20 μm.

A bonding material such as Ag powder, an Ag sheet, or the like can be used as the bonding layer 3, which mutually bonds the metal circuit board 2 and semiconductor chip 1. The thermal conductivity of the bonding layer 3 is preferably 80 W/m·k or more. To increase the thermal conductivity, Ag powder or an Ag sheet should be used as the bonding material.

A brazing material 4 made of Ag—Cu—In—Ti filler is preferably used for bonding between the carbon fiber-metal composite 5 and the metal circuit board 2 formed on its top surface, between the carbon fiber-metal composite 5 and the silicon nitride insulated substrate 7 disposed on its bottom surface, and between the silicon nitride insulated substrate 7 and the heat dissipating plate 8 made of Cu or a Cu alloy, which is disposed on its bottom surface.

As for the carbon fiber-metal composite 5, the thermal conductivity of the carbon fiber itself is about 1000 W/m·k, which is about 2.5 times the thermal conductivity (390 W/m·k) of a Cu alloy or Cu, which is a matrix metal, so the orientation direction of the carbon fiber largely contributes to the thermal conductivity of the carbon fiber-metal composite 5. Therefore, if a carbon fiber-metal composite in which carbon is oriented in one direction is disposed in its thickness direction, the thermal resistance of the power semiconductor module can be reduced.

There is no restriction on the carbon fiber of the carbon fiber-metal composite 5 if the carbon fiber has a relatively high thermal conductivity. An example is TORAYCACLOTH from Toray Industries, Inc.; it is of a carbon fabrics type. Alternatively, purified wood tar may be heated under a reduced pressure to form pitch, after which melt spinning is carried out for the formed pitch to form pitch fiber and then the pitch fiber is carbonized to form carbon fiber. In this case, the purified wood tar is heated under a reduced pressure in a range of 2 to 10 mmHg at a temperature in a range of 100° C. to 220° C. to form the pitch. The pitch obtained in the above process is crushed, and then melt spinning is carried out at a temperature in a range of 140° C. to 180° C. by using a nitrogen gas pressure to form pitch fiber. A process for carbonizing the obtained pitch into carbon fiber can be performed under the same conditions as in a conventional process in which pitch obtained from petroleum or coal is used as raw material.

Next, the method of bonding the metal circuit board, the carbon fiber-metal composite, the ceramic material, and Cu or a Cu alloy that constitute the power semiconductor module in this embodiment will be described. The carbon fiber-metal composite 5 is shaped to a size of 50 mm×30 mm×3 mm (thickness). The surface layers 6 are formed on the surfaces of the carbon fiber-metal composite 5. The metal circuit board 2 is a Cu plate measuring 50 mm×30 mm×0.1 mm (thickness). The heat dissipating plate 8 is an oxygen-free Cu base measuring 85 mm×50 mm×3 mm (thickness). The insulating layer disposed between the carbon fiber-metal composite 5 and the heat dissipating plate 8 is the silicon nitride insulated substrate 7 measuring 50 mm×30 mm×0.32 mm (thickness). In the manufacturing of the silicon nitride insulated substrate 7, a green sheet, which is superior in mass production, was formed in a sheet molding method, after which debinding was performed for six hours at 500° C. and sintering was performed for two to six hours at 1800° C. to 1950° C. in a nitrogen ambience under a pressure of nine atmospheres, producing a sintered sheet. The surfaces of the sintered sheet were sandblasted with abrasive grains made of 300-mesh alumina.

By a screen printing method, an Ag—Cu—In filler metallic brazing material was applied to the front surface of the carbon fiber-metal composite 5 and an Ag—Cu—In—Ti filler metallic brazing material was applied to the back surface. The Ag—Cu—In—Ti filler metallic brazing material was also applied to one surface of the silicon nitride insulated substrate 7. The metal circuit board 2, the carbon fiber-metal composite 5, the front and back surfaces of which were coated with brazing materials, the silicon nitride insulated substrate 7, and the heat dissipating plate 8 were attached to a carbon brazing tool from the front of the carbon brazing tool. A ceramic spring was used to apply a load of 0.1 MPa to the brazing tool. The silicon nitride insulated substrate 7 was attached in such a way that the surface on which the brazing material was applied was bonded to the Cu base plate. The brazing tool was placed in a vacuum brazing vessel with a vacuum degree of 2.0×10⁻³ Pa and held at 760° C. for 10 minutes, causing the metal circuit 2, carbon fiber-metal composite 5, and heat dissipating plate 8 to be bonded simultaneously.

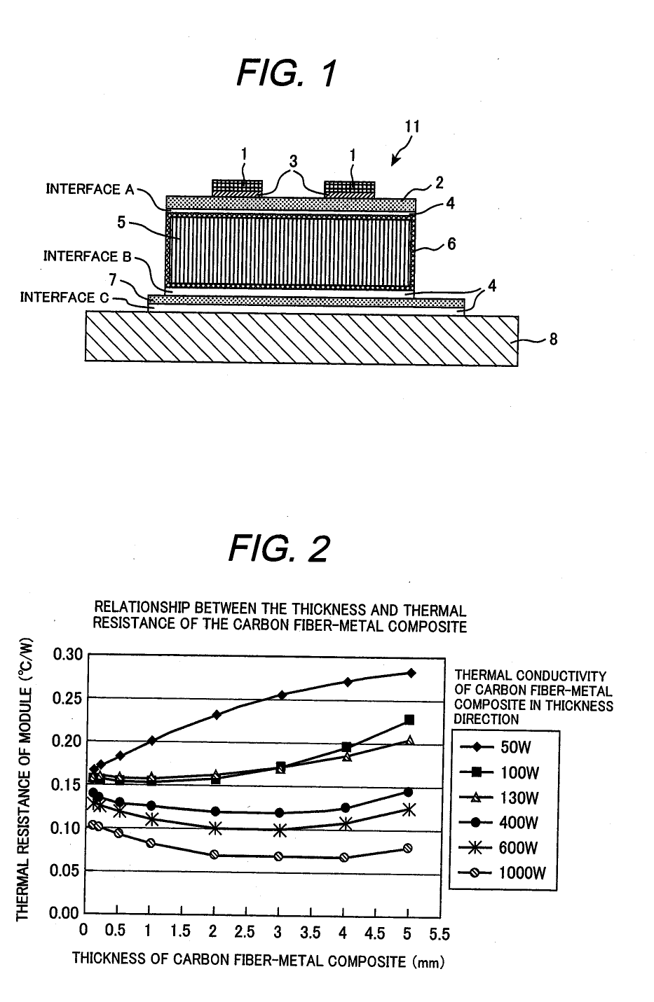

To mount the semiconductor chip 1, a bonding method in which nano Ag particles are used was employed. To form the bonding layer 3 below the semiconductor chip 1, nano Ag powder particles were used, 0.5% polyacrylic acid being applied to the particle surface in advance, a primary particle diameter being in a range of 20 to 500 nm. The nano Ag paste were applied to the bonding surface of the metal circuit board 2, and the metal circuit 2 and semiconductor chip 1 were heated in the atmosphere at temperatures from 200° C. to 350° C. for three minutes under a load pressure of 1.0 MPa so as to mutually bond the metal circuit board 2 and semiconductor chip 1, producing the power semiconductor module shown in FIG. 2.

The effects of the bonding layer 3, brazing material 4, carbon fiber-metal composite 5, surface layer 6, silicon nitride insulated substrate 7, and heat dissipating plate 8 that constitute the power semiconductor module 11 will be described below.

FIG. 2 is a graph illustrating relationship among the thermal conductivity and thickness of the carbon fiber-metal composite 5 used in the power semiconductor module 11 according to the present invention, and thermal resistance of the power semiconductor module 11. The thermal conductivity of the carbon fiber-metal composite is denoted W in the drawing.

In evaluation described below, a semiconductor chip measuring 12 mm×12 mm, the number of semiconductor chips being 1, a Cu circuit board measuring 50 mm×30 mm×0.1 mm (thickness), a carbon fiber-metal composite measuring 50 mm×30 mm, a heat dissipating plate measuring 85 mm×50 mm×3 mm (thickness), and a bonding layer, having a thermal conductivity of 180 W/m·k, formed by using nano Ag powder particles below the semiconductor chip were used. The thickness of the Cu surface layer of the carbon fiber-metal composite was 5 μm. The thermal resistance (Rj-w) of the power semiconductor module 11 is affected by the thermal conductivity and thickness of the carbon fiber-metal composite. When the thermal conductivity of the carbon fiber-metal composite was 50 W/m·k, the carbon fiber-metal composite itself did not contribute heat dissipation; as its thickness increased, Rj-w increased.

When the thermal conductivity of the carbon fiber-metal composite was about 100 W/m·k, it began to contribute heat dissipation; when its thickness was increased to 0.5 mm, Rj-w was reduced; however, when the thickness was 1 mm or more, Rj-w was increased. That is, there is an appropriate thickness for the carbon fiber-metal composite. In this case, however, Rj-w cannot be reduced to or below 0.15° C./W, which is required for power modules.

When the thermal conductivity of the carbon fiber-metal composite in the thickness direction was increased to 400 W/m·k, Rj-w could be reduced to or below 0.15° C./W in a thickness range of 0.2 to 5 mm.

Accordingly, it is preferable that the thermal conductivity of the carbon fiber-metal composite is 400 W/m·k or more. It is further preferable that the thickness of the carbon fiber-metal composite falls to a range of 2.5 to 3.5 mm.

The thermal conductivities, in the thickness direction, of carbon fiber-metal composites used to evaluate the thermal resistance of the inventive power semiconductor module were 50 W/m·k, 100 W/m·k, 130 W/m·k, 600 W/m·k, and 1000 W/m·k. The materials of these carbon fiber-metal composites were carbon fiber and Cu. The carbon fiber-metal composite with a thermal conductivity of 50 W/m·k included non-oriented fiber carbon by 30 volume percent. The carbon fiber-metal composite with a thermal conductivity of 100 W/m·k included fiber carbon oriented in one direction by 30 volume percent. The carbon fiber-metal composite with a thermal conductivity of 130 W/m·k included fiber carbon oriented in one direction by 36 volume percent. The carbon fiber-metal composite with a thermal conductivity of 600 W/m·k included fiber carbon oriented in one direction by 52 volume percent. The carbon fiber-metal composite with a thermal conductivity of 1000 W/m·k included fiber carbon oriented in one direction by 80 volume percent. A thermal property evaluation apparatus from Kyoto Electronics Manufacturing Co., Ltd. was used to measure the thermal conductivities of the carbon fiber-metal composites. The measurement was performed by a laser flush method. Samples used in measurement were machined to a size of 10 mm in diameter×3-mm thickness.

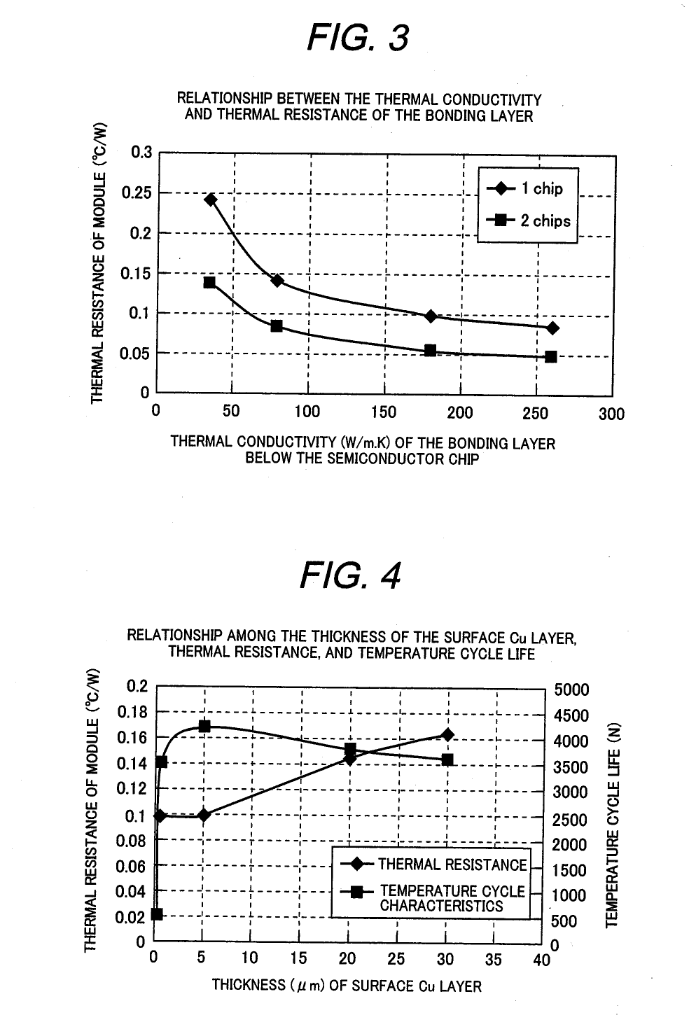

FIG. 3 is a graph illustrating relationship between the thermal conductivity of the bonding layer, which is disposed below the semiconductor chip and used in the inventive power semiconductor module, and the thermal resistance of the power semiconductor module. The graph shows a case in which one semiconductor chip was mounted (one-chip configuration) and another case in which two semiconductor chips were mounted (two-chip configuration). In evaluation described below, a semiconductor chip measuring 12 mm×12 mm, a Cu circuit board measuring 50 mm×30 mm×0.1 mm (thickness), a carbon fiber-metal composite measuring 50 mm×30 mm×3 mm (thickness), and a heat dissipating plate measuring 85 mm×50 mm×3 mm (thickness) were used, the thermal conductivity of the carbon fiber-metal composite being 400 W/m·k, the thickness of the Cu surface layer of the carbon fiber-metal composite being 5 μm.

When lead-free solder was used for the bonding layer below the semiconductor chip, the thermal resistance Rj-w could be reduced to or below 0.15° C./W in the two-chip configuration, as required for power modules. In the one-chip configuration, however, Rj-w was 0.24° C./W, making the power semiconductor module inappropriate to be mounted in an inverter for an HEV.

When the thermal conductivity of the bonding layer was 80 W/m·k or more, the thermal resistance could be reduced to Rj-w value to a desired value, 0.15° C./W or less, even in the one-chip configuration. In addition, since the number of semiconductor chips was reduced, cost reduction is possible. Accordingly, the desired thermal conductivity of the bonding layer used in the present invention is 80 W/m·k or more.

The bonding layers used to evaluate the thermal resistance of the inventive power semiconductor module were made of different materials. The bonding layer with the heat conductivity of 35 W/m·k was made of lead-free solder with a composition of Sn-3 wt % Ag-0.5 wt % Cu. The bonding layer with the heat conductivity of 80 W/m·k was made of nano Ag powder with a void ratio of 35% by volume. The bonding layer with the heat conductivity of 130 W/m·k was made of nano Ag powder with a void ratio of 6% by volume. The bonding layer with the heat conductivity of 180 W/m·k was made of nano Ag powder with a void ratio of 2.5% by volume. The bonding layer with the heat conductivity of 260 W/m·k was made of nano Ag powder with a void ratio of 0.5% by volume. The thicknesses of these bonding layers were adjusted within a range of 0.76 to 0.87 μm.

To form the bonding layers made of nano Ag powder, nano Ag powder particles, a primary particle diameter of which is within a range of 20 to 500 nm, were used. Polyacrylic acid with a concentration of 0.5% was applied to the particle surface in advance. Polyacrylic acid has appropriate adherence, and is oxidized and disappears when heated in the atmosphere. Therefore, polyacrylic acid enables the semiconductor chip and wires to be easily positioned before bonding is performed. Upon completion of the bonding, the polyacrylic acid disappears, so it does not impede ease of bonding. Although polyacrylic acid was used in this embodiment, it will be appreciated that other adhesives can be used.

The above void ratios were adjusted in the atmosphere within a temperature range of 200° C. to 350° C. while heating was performed for three minutes under a load pressure of 1.0 MPa.

FIG. 4 is a graph illustrating relationship among the thickness of the surface layer t1 of the carbon fiber composite, which is used in the inventive power semiconductor module, and the thermal resistance and temperature cycle life of the power semiconductor module. The power semiconductor module used in FIG. 4 was structured with a semiconductor chip measuring 12 mm×12 mm, a Cu circuit board measuring 50 mm×30 mm×0.1 mm (thickness), a carbon fiber-metal composite measuring 50 mm×30 mm×3 mm (thickness), and a heat dissipating plate measuring 85 mm×50 mm×3 mm (thickness), the thermal conductivity of the carbon fiber-metal composite being 400 W/m·k. To measure the thermal resistance of the power semiconductor module, current at 200 A was supplied to the module for 30 seconds and a saturated thermal resistance was measured. The temperature cycle fatigue life was measured as the number of cycles needed until the thermal resistance of the power semiconductor module was increased to 1.2 times its initial thermal resistance.

When the thickness of the surface layer t1 was 0.5 μm or less, reaction between the surface layer of the carbon fiber composite and the brazing material layer could be maintained, lowering the strength of bonding between the carbon fiber composite and the silicon nitride substrate. Accordingly, the temperature cycle characteristics against repetitions of heating and cooling was lowered, and a crack developed on the interface between the carbon fiber composite and the silicon nitride substrate after 500 cycles in a thermal shock test. The thermal resistance then became 50% more than the initial thermal resistance, applying an excessive thermal load to the semiconductor chip and disabling the power semiconductor module from operating as a power module.

When the thickness t1 exceeded 20 μm, the thermal conductivity of the surface layer itself of the carbon fiber composite having a lower thermal conductivity than carbon fiber became a limiting factor and thus the thermal resistance of the power semiconductor module became 0.15° C./W or more.

Accordingly, the thickness of the surface layer t1 of the carbon fiber composite used in the power semiconductor module is preferably within a range of 0.5 to 20 μm.

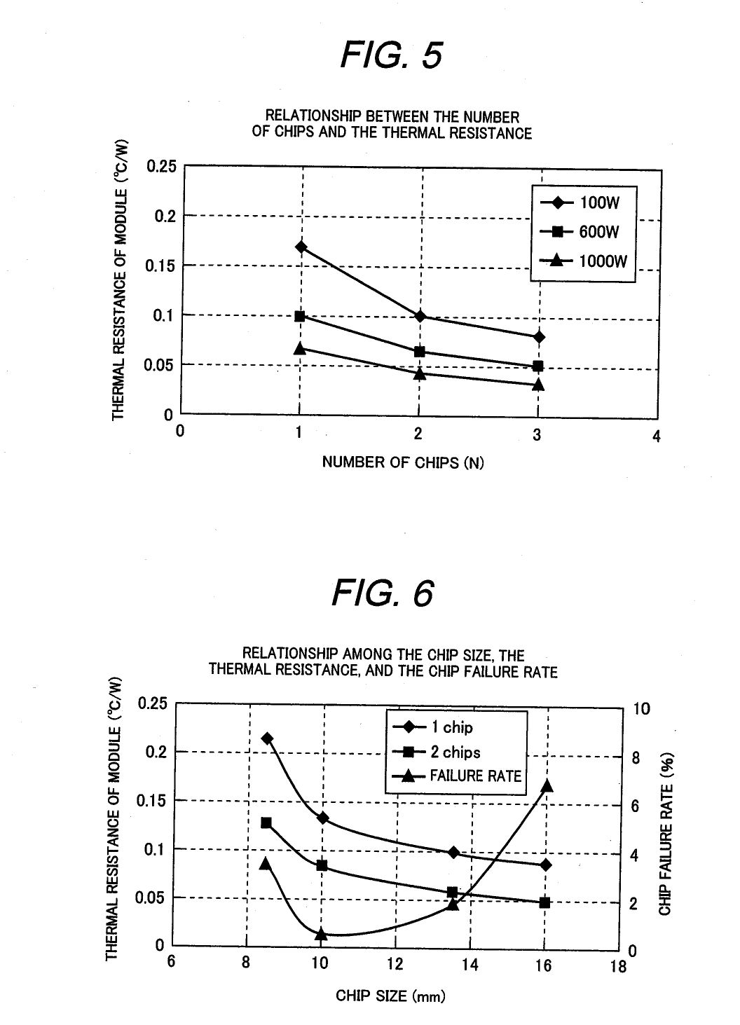

FIG. 5 is a graph illustrating relationship between the thermal conductivity of the carbon fiber composite, which is used in the inventive power semiconductor module, the number of semiconductor chips, and the thermal resistances of the power semiconductor module. The thermal conductivity of the carbon fiber-metal composite is denoted W in the drawing.

The power semiconductor module used in FIG. 5 was structured with a Cu circuit board measuring 50 mm×30 mm×0.1 mm (thickness), a carbon fiber-metal composite measuring 50 mm×30 mm×3 mm (thickness), and a heat dissipating plate measuring 85 mm×50 mm×3 mm (thickness), the thermal conductivity of the carbon fiber-metal composite being 400 W/m·k, the thickness of the Cu surface layer of the carbon fiber-metal composite being 5 μm.

As the number of semiconductors mounted increased, the thermal resistance of the power semiconductor module decreased. When the thermal conductivity of the carbon fiber composite was 400 W/m·k or less, the thermal resistance was 0.15° C./W or less even in the one-chip configuration. As described above, it is important for the power semiconductor module to satisfy both ease of heat dissipation and a low cost. To keep the thermal resistance to or below 0.15° C./W, it suffices to use at least two semiconductor chips. The area of the semiconductor chip and the number of semiconductor chips affect the cost of the semiconductor chip, so the two factors should be lowered. The reduction in the semiconductor chip area also saves space in which to mount the semiconductor chip. Accordingly, the thermal conductivity of the carbon fiber composite used in the present invention is preferably 400 W/m·k or more, and a one-chip configuration is preferable.

FIG. 6 is a graph illustrating relationship among the size of the semiconductor chip, which is used in the inventive power semiconductor module, the thermal resistance of the power semiconductor module, and the failure rate of the semiconductor chip. In evaluation described below, a Cu circuit board measuring 50 mm×30 mm×0.1 mm (thickness), a carbon fiber-metal composite measuring 50 mm×30 mm×3 mm (thickness), and a heat dissipating plate measuring 85 mm×50 mm×3 mm (thickness) were used, the thermal conductivity of the carbon fiber-metal composite being 400 W/m·k, the thickness of the Cu surface layer of the carbon fiber-metal composite being 5 μm.

As the size (area) of the power semiconductor module increased, the thermal resistance of the power semiconductor module decreased. When the semiconductor chip measuring 10 mm×10 mm was used, the ratio of faults caused in the semiconductor chip was reduced to 0.9%, which is the lowest value. It is important for the power semiconductor module to satisfy both ease of heat dissipation and a low cost. To keep the thermal resistance to or below 0.15° C./W, it suffices to use a power semiconductor module with a size of 10 mm×10 mm or more. The area of the semiconductor chip and the number of semiconductor chips affect the cost of the semiconductor chip, so the two factors should be lowered. The reduction in the semiconductor chip area also saves space in which to mount the semiconductor chip. Accordingly, the size of the semiconductor chip mounted in the present invention is preferably 10 mm×10 mm, and a one-chip configuration is preferable.

Table 1 indicates results of power semiconductor module evaluation that was carried out in terms of the brazing material composition of the brazing material 4, bonding temperature, the void ratio on the bonding interface, and brazing material flow. In Table 1, interface A is a bonding interface between the Cu circuit board and the carbon fiber composite, interface B is a bonding interface B between the carbon fiber composite and the silicon nitride substrate, and interface C is a bonding interface between the silicon nitride substrate and the heat dissipating plate made of Cu or a Cu alloy (see FIG. 1). To evaluate the void ratio on each bonding interface, Hi-Focuse, which is an ultrasonic image diagnosis apparatus from Hitachi Construction Co., Ltd., was used. The void ratio was calculated as a ratio of the areas of voids to the area of each interface, which was taken as 100%. The void ratio on each interface is preferably 5% or less from the viewpoint of the bonding strength and ease of heat dissipation. The brazing material flow is a phenomenon in which the Ag component of the brazing material spreads on the surfaces of the metal circuit board and the heat dissipating plate made of Cu or a Cu alloy. In this evaluation, when the Ag component spread 2 mm or more from an edge of the interfaces A, B, and C, it was judged that the brazing material flowed. When there is a brazing material flow, the appearance of the power semiconductor module becomes uneven, the plated surface becomes coarse, and solder wettability is lowered. Accordingly, it is essential to prevent the brazing material from flowing.

TABLE 1
Table 1

| | | | | | | Void ratio on the | | | |
|---|---|---|---|---|---|---|---|---|---|
| | | | | | Brazing | bonding interface (%) | | | Brazing |
| | | Brazing alloy composition | | | temperature | Interface | Interface | Interface | alloy |
| | No. | Interface A | Interface B | Interface C | (° C.) | A | B | C | flow out |
| Examples | 1 | Ag—25Cu—10In | Ag—25Cu—10In—2Ti | Ag—25Cu—10In—2Ti | 680 | 3.5 | 3.3 | 3.6 | No |
| | 2 | Ag—25Cu—10In | Ag—25Cu—10In—2Ti | Ag—25Cu—10In—2Ti | 750 | 0.8 | 0.8 | 0.9 | No |
| | 3 | Ag—20Cu—5In | Ag—25Cu—10In—2Ti | Ag—25Cu—10In—2Ti | 680 | 4.2 | 4.2 | 4.5 | No |
| | 4 | Ag—20Cu—5In | Ag—25Cu—10In—2Ti | Ag—25Cu—10In—2Ti | 750 | 1.2 | 0.7 | 0.6 | No |
| | 5 | Ag—25Cu—10In | Ag—20Cu—5In—2Ti | Ag—20Cu—5In—2Ti | 680 | 3.6 | 4.4 | 4.5 | No |
| | 6 | Ag—25Cu—10In | Ag—20Cu—5In—2Ti | Ag—20Cu—5In—2Ti | 750 | 0.9 | 1.2 | 1.1 | No |
| Com- | 21 | Ag—25Cu | Ag—25Cu—10In—2Ti | Ag—25Cu—10In—2Ti | 750 | 32 | 0.9 | 1.1 | No |
| parative | 22 | Ag—20Cu | Ag—25Cu—10In—2Ti | Ag—25Cu—10In—2Ti | 750 | 25 | 0.7 | 0.8 | No |
| examples | 23 | Ag—25Cu—10In | Ag—25Cu—2Ti | Ag—25Cu—2Ti | 750 | 0.6 | 31 | 25 | No |
| | 24 | Ag—25Cu—10In | Ag—20Cu—2Ti | Ag—20Cu—2Ti | 750 | 0.5 | 23 | 29 | No |
| | 25 | Ag—25Cu—10In | Ag—25Cu—10In—2Ti | Ag—25Cu—10In—2Ti | 500 | 43 | 60 | 53 | No |
| | 26 | Ag—25Cu—10In | Ag—25Cu—10In—2Ti | Ag—25Cu—10In—2Ti | 560 | 42 | 44 | 47 | No |
| | 27 | Ag—25Cu—10In | Ag—25Cu—10In—2Ti | Ag—25Cu—10In—2Ti | 820 | 0.5 | 0.4 | 0.5 | Yes |
| | 28 | Ag—25Cu—10In | Ag—25Cu—10In—2Ti | Ag—25Cu—10In—2Ti | 850 | 0.4 | 0.4 | 0.3 | Yes |

In examples 1 to 6 in Table 1, the compositions of the brazing materials on interface A were Ag-25Cu-10In and Ag-25Cu-5In, and the compositions of the brazing materials on interfaces B and C were Ag-25Cu-10In-2Ti and Ag-25Cu-5In-2Ti. Bonding was carried out at 680° C. and 750° C. On all interfaces in examples 1 to 6, the bonding surface void ratio was suppressed to 4.5% or less and a well-bonded state was obtained. There was no brazing material flow.

In comparative examples 21 and 22 in Table 1, the brazing materials on interface A were Ag—Cu filler metallic brazing materials free from In, their compositions being Ag-25Cu and Ag-20Cu. Bonding was carried out at 750° C. In comparative examples 21 and 22, the melting points of the brazing materials increased and the void ratios on interface A exceeded 5%.

In comparative examples 23 and 24 in Table 1, the brazing materials on interfaces B and C were Ag—Cu—Ti filler metallic brazing materials free from In, their compositions being Ag-25Cu-2Ti and Ag-20Cu-2Ti. Bonding was carried out at 750° C. As in comparative examples 21 and 22, the void ratios on interfaces B and C also exceeded 5% in comparative examples 23 and 24.

The compositions of the brazing materials in comparative examples 25 to 28 were the same as in examples 1 and 2 in Table 1, but the bonding temperature was 500° C., 560° C., 820° C., and 850° C., respectively. In comparative examples 25 and 26, in which the bonding temperature was lower than 600° C., the void ratio on interfaces A, B, and C exceeded 5%. In comparative examples 27 and 28, in which the bonding temperature was higher than 800° C., the void ratio on interfaces A, B, and C was 5% or lower but brazing material components flowed on the metal circuit board and heat dissipating plate.

It is found from the above results that when In is included in the brazing materials on interfaces A, B, and C, the bonding interface void ratio can be reduced. In particular, the Ag—Cu—In filler metallic brazing material is preferable on interface A, and the Ag—Cu—In—Ti filler metallic brazing material is preferable on interfaces B and C. A preferable composition of the Ag—Cu—In filler metallic brazing material is 75Ag-25Cu—10In, a preferable composition of the Ag—Cu—In—Ti filler metallic brazing material is 75Ag-25Cu-10In-2Ti. Preferable bonding temperatures are 600° C. to 800° C.

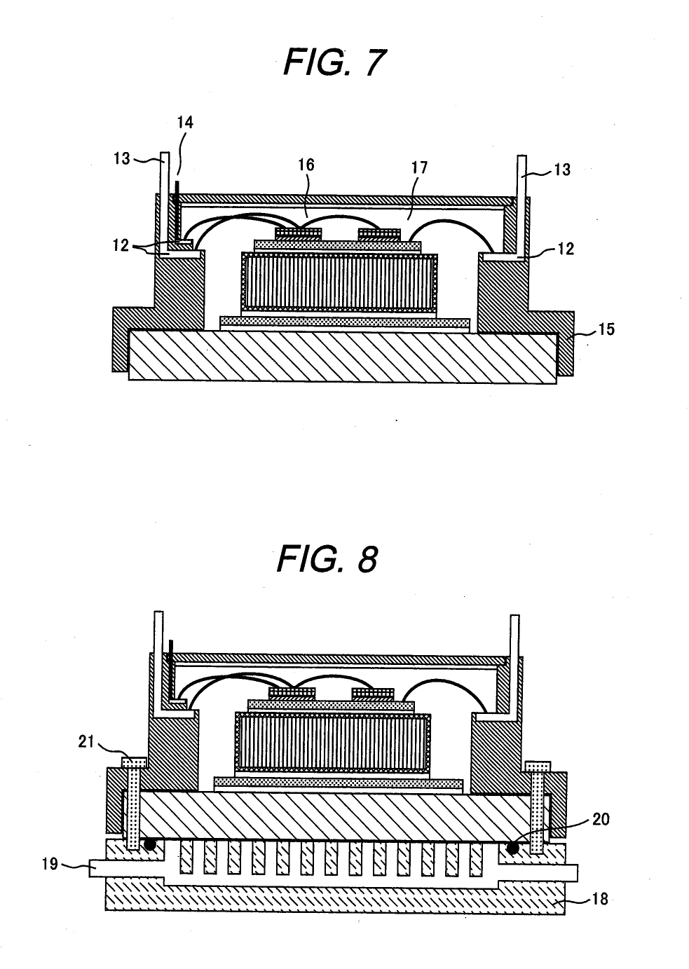

Another embodiment of the present invention will be described next. FIG. 7 is a cross sectional view illustrating the structure of a power semiconductor module according to the other embodiment of the present invention. To obtain the power semiconductor module, a PPS plastic case 15 and the heat dissipating plate 8 are bonded to the power semiconductor module shown in FIG. 1 with a polyimide adhesive; in this bonding, heating was carried out at 130° C. for three hours in the atmosphere. Wire pads 12 are disposed on the semiconductor chip 1, metal circuit board 2, and PPS plastic case 15. Wire bonding was performed for the wire pads 12 by using A1 wires 16 with a diameter of 400 μm. Insulating gel 17 was then supplied into the module, and heated at 160° C. for three hours in the atmosphere so as to be cured.

A cooling jacket 18 is also attached to the back of the heat dissipating plate 8, forming a power semiconductor module shown in FIG. 8. Bolts 21 are used to fix the cooling jacket 18 to the back of the heat dissipating plate 8 through a waterproof sheet 20 around the outer peripheries of the PPS plastic case 15 and heat dissipating plate 8. The waterproof sheet 20 is disposed inside the bolts 21. The cooling jacket 18 has coolant channels 19 through which coolant flows. The flow rate and pressure of the coolant can be controlled with a water pump. In this cooling structure, the coolant flowing in the coolant channels 19 in the cooling jacket 18 is directly brought into contact with the heat dissipating plate 8. For comparison purposes, FIG. 10 shows a conventional indirect cooling structure, in which the front surface of the cooling jacket 18 made of an aluminum die-casting is attached to the back of the heat dissipating plate of the power semiconductor module through heat dissipation grease 22. The direct cooling structure in this embodiment is superior to the conventional cooling structure in heat dissipation.

The thermal resistance (° C./W) and temperature cycle characteristics of the power semiconductor module shown in FIG. 8 were then evaluated as power semiconductor module characteristics. With power semiconductor modules manufactured for this evaluation, the thermal conductivity and thickness of the carbon fiber-metal composite, the material and thickness of the surface layer, the semiconductor chip size, the number of semiconductor chips, the material and thermal conductivity of the bonding layer below the semiconductor chip, the flow rate of coolant, and the water pressure were changed. Table 2 shows evaluation results. The unit of the semiconductor chip size indicates a length and width; for example, 13.5 mm² indicates that the semiconductor chip is 13.5 mm long and 13.5 mm wide.

TABLE 2
Table 2

| | | Carbon fiber-metal composite | | | | | | Semiconductor | |
|---|---|---|---|---|---|---|---|---|---|
| | | Thermal conductivity | | | | | | device | |
| Example/ | | (W/m · k) | | | | Surface | | | Number of |
| comparative | | Z | X | Y | Thickness | layer | Thickness | Size | semiconductor |
| example | No. | direction | direction | direction | (μm) | Material | (μm) | (mm²) | devices |
| Examples | 1 | 600 | 600 | 120 | 2 | Cu | 5 | 13.5 | 1 |
| | 2 | 600 | 600 | 120 | 3 | Cu | 5 | 13.5 | 1 |
| | 3 | 600 | 600 | 120 | 4 | Cu | 5 | 13.5 | 1 |
| | 4 | 600 | 600 | 120 | 2 | Ni | 5 | 13.5 | 1 |
| | 5 | 600 | 600 | 120 | 3 | Ni | 5 | 13.5 | 1 |
| | 6 | 600 | 600 | 120 | 3 | Cu | 1 | 13.5 | 1 |
| | 7 | 600 | 600 | 120 | 3 | Cu | 10 | 13.5 | 1 |
| | 8 | 600 | 600 | 120 | 3 | Cu | 15 | 13.5 | 1 |
| | 9 | 600 | 600 | 120 | 3 | Cu | 20 | 13.5 | 1 |
| | 10 | 600 | 600 | 120 | 3 | Cu | 5 | 13.5 | 1 |
| | 11 | 600 | 600 | 120 | 3 | Cu | 5 | 13.5 | 1 |
| | 12 | 600 | 600 | 120 | 3 | Cu | 5 | 13.5 | 1 |
| | 13 | 600 | 600 | 120 | 3 | Cu | 5 | 13.5 | 1 |
| | 14 | 600 | 600 | 120 | 3 | Cu | 5 | 13.5 | 1 |
| | 15 | 600 | 600 | 120 | 3 | Cu | 5 | 13.5 | 1 |
| | 16 | 600 | 600 | 120 | 3 | Cu | 5 | 13.5 | 1 |
| | 17 | 600 | 600 | 120 | 3 | Cu | 5 | 13.5 | 1 |
| | 18 | 600 | 600 | 120 | 3 | Cu | 5 | 13.5 | 1 |
| | 19 | 600 | 600 | 120 | 3 | Cu | 5 | 13.5 | 1 |
| | 20 | 600 | 600 | 120 | 3 | Cu | 5 | 13.5 | 1 |
| | 21 | 600 | 600 | 120 | 3 | Cu | 5 | 13.5 | 1 |
| | 22 | 600 | 600 | 120 | 3 | Cu | 5 | 10 | 1 |
| | 23 | 600 | 600 | 120 | 3 | Cu | 5 | 13.5 | 2 |
| | 24 | 600 | 600 | 120 | 3 | Cu | 5 | 13.5 | 2 |
| | 25 | 600 | 600 | 120 | 3 | Cu | 5 | 13.5 | 3 |
| | 26 | 600 | 600 | 120 | 3 | Cu | 5 | 13.5 | 3 |
| | 27 | 600 | 600 | 200 | 3 | Cu | 5 | 13.5 | 1 |
| | 28 | 600 | 500 | 120 | 3 | Cu | 5 | 13.5 | 1 |
| | 29 | 400 | 400 | 100 | 2 | Cu | 5 | 13.5 | 1 |
| | 30 | 400 | 400 | 100 | 3 | Cu | 5 | 13.5 | 1 |
| | 31 | 400 | 400 | 100 | 3 | Cu | 10 | 13.5 | 1 |
| | 32 | 400 | 400 | 100 | 3 | Cu | 5 | 13.5 | 1 |
| | 33 | 1000 | 1000 | 200 | 2 | Cu | 5 | 13.5 | 1 |
| | 34 | 1000 | 1000 | 200 | 3 | Cu | 5 | 13.5 | 1 |
| | 35 | 1000 | 1000 | 200 | 3 | Cu | 10 | 13.5 | 1 |
| | 36 | 1000 | 1000 | 200 | 3 | Cu | 5 | 13.5 | 1 |
| Comparative | 51 | 50 | 50 | 50 | 3 | Cu | 5 | 13.5 | 1 |
| examples | 52 | 100 | 100 | 100 | 3 | Cu | 5 | 13.5 | 1 |
| | 53 | 130 | 130 | 130 | 3 | Cu | 5 | 13.5 | 1 |
| | 54 | 600 | 600 | 120 | 3 | Cu | 0.4 | 13.5 | 1 |
| | 55 | 600 | 600 | 120 | 3 | Cu | 25 | 13.5 | 1 |
| | 56 | 600 | 600 | 120 | 3 | Cu | 5 | 13.5 | 1 |
| | 57 | 600 | 600 | 120 | 3 | Cu | 5 | 13.5 | 1 |
| | 58 | 600 | 600 | 120 | 3 | Cu | 5 | 13.5 | 1 |
| | 59 | 600 | 600 | 120 | 3 | Cu | 5 | 13.5 | 1 |
| | 60 | 600 | 600 | 120 | 3 | Cu | 5 | 13.5 | 1 |
| | 61 | 600 | 600 | 120 | 3 | Cu | 5 | 13.5 | 1 |
| | 62 | 600 | 600 | 120 | 3 | Cu | 5 | 13.5 | 1 |

| | | Bonding layer below | | | | | |
|---|---|---|---|---|---|---|---|
| | | semiconductor device | | Cooling capacity | | Module characteristics | |
| Example/ | | | Thermal | Water flow | Water | Thermal | Temperature |
| comparative | | | conductivity | rate | pressure | resistance | cycle fatigue |
| example | No. | Material | (W/m · k) | (liters/min) | (kPa) | (° C./W) | life (times) |
| Examples | 1 | Nano Ag | 180 | 10 | 15 | 0.101 | >3000 |
| | 2 | Nano Ag | 180 | 10 | 15 | 0.100 | >3000 |
| | 3 | Nano Ag | 180 | 10 | 15 | 0.110 | >3000 |
| | 4 | Nano Ag | 180 | 10 | 15 | 0.108 | >3000 |
| | 5 | Nano Ag | 180 | 10 | 15 | 0.110 | >3000 |
| | 6 | Nano Ag | 180 | 10 | 15 | 0.093 | >3000 |
| | 7 | Nano Ag | 180 | 10 | 15 | 0.115 | >3000 |
| | 8 | Nano Ag | 180 | 10 | 15 | 0.125 | >3000 |
| | 9 | Nano Ag | 180 | 10 | 15 | 0.142 | >3000 |
| | 10 | Ag sheet | 180 | 10 | 15 | 0.112 | >3000 |
| | 11 | Ag sheet | 280 | 10 | 15 | 0.089 | >3000 |
| | 12 | Nano Ag | 220 | 10 | 15 | 0.091 | >3000 |
| | 13 | Nano Ag | 400 | 10 | 15 | 0.086 | >3000 |
| | 14 | Ag sheet | 180 | 10 | 15 | 0.085 | >3000 |
| | 15 | Ag sheet | 180 | 10 | 15 | 0.080 | >3000 |
| | 16 | Nano Ag | 180 | 12 | 15 | 0.096 | >3000 |
| | 17 | Nano Ag | 180 | 15 | 15 | 0.096 | >3000 |
| | 18 | Nano Ag | 180 | 20 | 15 | 0.092 | >3000 |
| | 19 | Nano Ag | 180 | 10 | 10 | 0.112 | >3000 |
| | 20 | Nano Ag | 180 | 10 | 20 | 0.100 | >3000 |
| | 21 | Nano Ag | 180 | 10 | 40 | 0.008 | >3000 |
| | 22 | Nano Ag | 180 | 10 | 15 | 0.142 | >3000 |
| | 23 | Nano Ag | 180 | 10 | 15 | 0.082 | >3000 |
| | 24 | Nano Ag | 180 | 10 | 15 | 0.060 | >3000 |
| | 25 | Nano Ag | 180 | 10 | 15 | 0.051 | >3000 |
| | 26 | Nano Ag | 180 | 10 | 15 | 0.042 | >3000 |
| | 27 | Nano Ag | 180 | 10 | 15 | 0.095 | >3000 |
| | 28 | Nano Ag | 180 | 10 | 15 | 0.112 | >3000 |
| | 29 | Nano Ag | 180 | 10 | 15 | 0.132 | >3000 |
| | 30 | Nano Ag | 180 | 10 | 15 | 0.130 | >3000 |
| | 31 | Nano Ag | 180 | 10 | 15 | 0.130 | >3000 |
| | 32 | Nano Ag | 280 | 10 | 15 | 0.120 | >3000 |
| | 33 | Nano Ag | 180 | 10 | 15 | 0.071 | >3000 |
| | 34 | Nano Ag | 180 | 10 | 15 | 0.070 | >3000 |
| | 35 | Nano Ag | 180 | 10 | 15 | 0.081 | >3000 |
| | 36 | Nano Ag | 280 | 10 | 15 | 0.068 | >3000 |
| Comparative | 51 | Nano Ag | 180 | 10 | 15 | 0.252 | >3000 |
| examples | 52 | Nano Ag | 180 | 10 | 15 | 0.170 | >3000 |
| | 53 | Nano Ag | 180 | 10 | 15 | 0.168 | >3000 |
| | 54 | Nano Ag | 180 | 10 | 15 | 0.158 | 200 |
| | 55 | Nano Ag | 180 | 10 | 15 | 0.165 | >3000 |
| | 56 | Nano Ag | 30 | 10 | 15 | 0.248 | 500 |
| | 57 | Nano Ag | 60 | 10 | 15 | 0.168 | 500 |
| | 58 | Ag sheet | 420 | 10 | 15 | 0.080 | >3000 |
| | 59 | Nano Ag | 180 | 4 | 15 | 0.168 | 500 |
| | 60 | Nano Ag | 180 | 2 | 15 | 0.185 | 500 |
| | 61 | Nano Ag | 180 | 10 | 3 | 0.165 | 100 |

| | | | | | |
|---|---|---|---|---|---|
| 62 | Nano Ag | 180 | 10 | 55 | Measurements could ont be |
| | | | | | carried out due to leakage |
| | | | | | of the coolant. |

The thermal resistance of the power semiconductor module was measured by using an apparatus for evaluating thermal resistances of power semiconductor chips, which is manufactured by Computer Aided Test Systems Inc. After a 200-A current was supplied for 30 seconds, the thermal resistance was evaluated. In evaluation of temperature cycle characteristics, the temperature was raised from −40° C. to room temperature and then to 125° C., after which the temperature was lowered to room temperature and then to −40° C. A success/failure decision was made according to the number of cycles required for the thermal resistance to be raised to 1.2 times the initial thermal resistance. It is preferable to maintain a reliability of 3000 cycles or more.

The X, Y, and Z directions in Table 2, in which the thermal conductivity of the carbon fiber-metal composite is measured, respectively indicate the thickness direction, the short-side direction, and the long-side direction.

The carbon fiber-metal composite 5 used in the evaluation was prepared by an energization pulse sintering method, in which carbon fiber as well as Cu and Cu powder with an average particle diameter of 1 μm to 200 μm were loaded in a carbon mold with a prescribed size. If the average particle diameter of Cu and Cu powder is less than 1 μm, the specific surface area becomes large and thus a copper oxide film is easily formed on particle surfaces, preventing a burning reaction from being facilitated. If the particle diameter is enlarged, a reaction to melt particles is less likely to occur, which impedes sintering. Accordingly, sintering was carried out at temperatures of 950° C. to 1030° C. for two hours under a pressure of 50 MPa in a nitrogen ambience. The thermal conductivity was adjusted by controlling the ratio between the amounts of carbon fiber and metal powder to be loaded as well as carbon orientation. Sintering is not limited to the energization pulse sintering method; an ordinary hot press method may also be used.

The cooling jacket used in the evaluation can be controlled by the water pump so that the water flow rate falls within a range of 0 to 30 liters/minute and the water pressure falls within a range of 0 to 100 kPa.

As indicated in Table 2, in evaluation of power semiconductor modules in examples 1 to 3, the thermal conductivities in the Z and X directions were 600 W/m·k and the thermal conductivity in the Y direction was 120 W/m·k; a carbon fiber-metal composite with a 5-um Cu layer was used as the surface layer; one semiconductor chip measuring 13.5 mm×13.5 mm was bonded by using a bonding layer below the semiconductor chip, which includes Ag powder and has a thermal conductivity of 180 W/m·k, as the bonding material; the water flow rate in the cooling jacket was 10 liters/minute; the pressure in the cooling jacket was 15 kPa; the thicknesses of the carbon fiber-metal composites in examples 1, 2, and 3 were respectively 2 μm, 3 μm, and 4 μm.

In examples 4 and 5, the material of the surface layers in examples 1 and 2 was changed to Ni. In examples 6 to 9, the surface layer thickness of the carbon fiber-metal composite in example 2 was changed to 1 μm, 10 μm, 15 μm, and 20 μm. In examples 10, 11, 14, and 15, the material of the bonding layer below the semiconductor chip in example 2 was changed to the Ag sheet and the thermal conductivity was changed to 180, 280, 320, and 400 W/m·k. In examples 12 and 13, the thermal conductivity below the semiconductor in example 2 was changed to 220 and 280 W/m·k. In examples 16 to 21, the water flow rate in example 2 was changed to 12, 15, and 20 liters/minute and the water pressure was changed to 10, 20, and 40 kPa. In examples 27 to 36, the size of the semiconductor chip or the number of semiconductors in example 2 was changed. In examples 27 to 36, the thermal conductivity and thickness of the carbon fiber-metal composite, the surface layer thickness, and the thermal conductivity of the bonding layer below the semiconductor chip in example 2 were changed.

The evaluation results indicate that the power semiconductor modules in examples 1 to 36 each achieve a thermal resistance (Rj-w) of 0.15° C./W or less and have superior temperature cycle characteristics.

By comparison, the power semiconductor modules in comparative examples 51 to 62 in Table 2 could not achieve a thermal resistance (Rj-w) of 0.15° C./W or less or could not have prescribed temperature cycle characteristics.

In comparative examples 51 to 53, the thermal conductivity in the thickness direction (Z direction) of the carbon fiber-metal composite in example 2 was changed to less than 400 W/m·k (50, 100, and 130 W/m·k). As a result, the thermal resistances of the power semiconductor modules exceeded 0.15° C.

In comparative example 54, the thickness of the Cu layer formed as the surface layer of the carbon fiber-metal composite in example 2 was changed to 0.4 μm. As a result, the thermal resistance of the power semiconductor module exceeded 0.15° C./W. This is because the surface layer is thin and the void ratio in the interface between the metal circuit board and the carbon fiber-metal composite increases, thereby increasing the thermal resistance.

In comparative example 55, the thickness of the Cu layer formed as the surface layer of the carbon fiber-metal composite in example 2 was changed to 25 μm. As a result, the thermal resistance of the power semiconductor module exceeded 0.15° C./W. It can be considered that the Cu surface layer is as thick as 25 μm and thus the Cu layer increases the thermal resistance.

In comparative examples 56 and 57, the thermal conductivity of the bonding layer below the semiconductor chip in example 2 was changed to 30 and 60 W/m·k. As a result, the thermal conductivities in both examples exceeded 0.15° C./W.

In comparative example 58, the material of the bonding layer below the semiconductor chip in example 2 was changed to the Ag sheet with a thermal conductivity of 420 W/m·k. The resulting power semiconductor module is superior in the thermal resistance and temperature cycle characteristics, but problematic in that it lacks ease of mass production that is necessary to produce products.

In comparative examples 59 and 60, the flow rate of the coolant in the cooling jacket was less than 5 litters/minute. The thermal resistance exceeded 0.15° C./W due to the insufficient cooling capacity.

In comparative example 61, the pressure of the coolant in the cooling jacket was less than 5 kPa. The thermal resistance exceeded 0.15° C./W due to the insufficient cooling capacity.

In comparative example 62, the pressure of the coolant in the cooling jacket exceeded 50 kPa. Since the cooling jacket caused a leakage of the coolant, the power semiconductor module could not function sufficiently.

Accordingly, the thermal conductivity of the carbon fiber-metal composite in the Z direction is preferably 400 W/m·k or more. The surface layer of the carbon fiber-metal composite may be made of Cu or Ni, and its thickness is preferably within a range of 0.5 to 20 μm. The thermal conductivity of the bonding layer below the semiconductor chip is preferably within a range of 80 to 400 W/m·L. The cooling jacket is preferably controlled by a water pump so that the water flow rate is 5 litters/minute or more and the water pressure falls within a range of 5 to 50 kPa.

Next, the vehicle-mounted inverter in which the inventive power semiconductor module is mounted will be described.

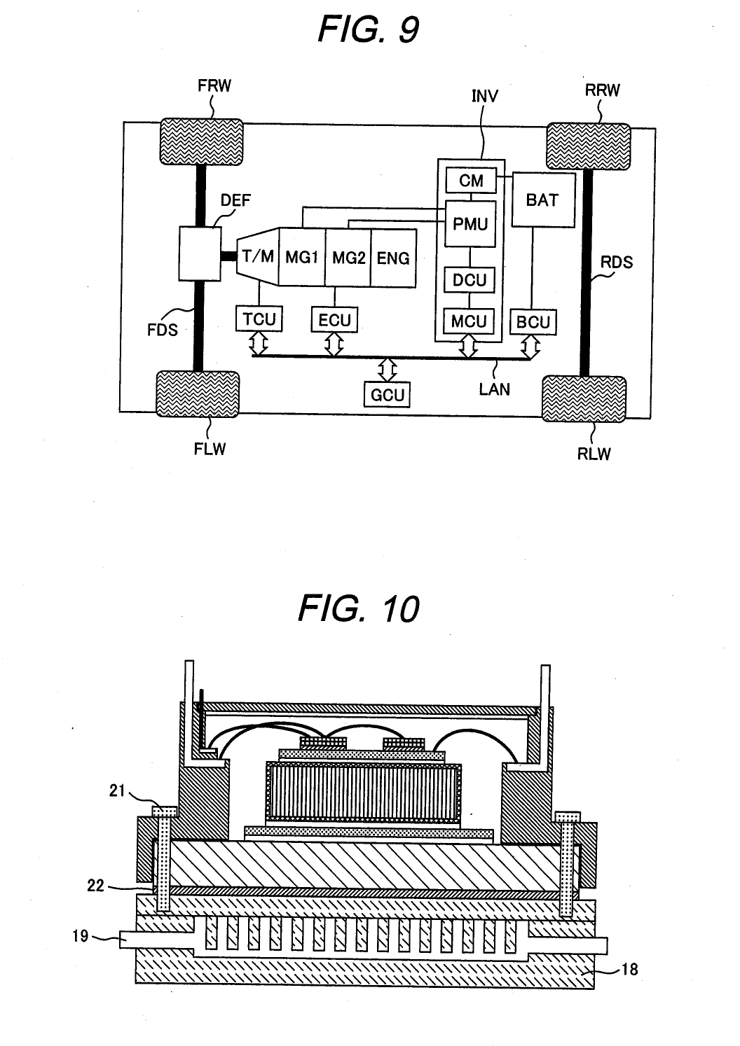

FIG. 9 is a block diagram of a hybrid electric vehicle that includes a vehicle-mounted electric system structured by using the inverter INV that uses the power semiconductor module according to the embodiment of the present invention and also has an engine system having an internal engine.

The HEV in this embodiment includes front wheels FRW and FLW, rear wheels RPW and RLW, a front wheel shaft FDS, a rear wheel shaft RDS, a differential gear DEF, a transmission T/M, an engine ENG, electric motors MG1 and MG2, the inverter INV, a battery BAT, an engine control unit ECU, a transmission control unit TCU, a motor control unit MCU, a battery control unit BCU, and a vehicle-mounted local area network LAN.

In this embodiment, a driving force is generated by the engine ENG and the two motors MG1 and MG2, and then transmitted through the transmission T/M, the differential gear DEF, and the front wheel shaft FDS to the front wheels FRW and FLW.

The transmission T/M, which comprises a plurality of gears, can change its gear ratio according to a speed and other operation parameters.

The differential gear DEF properly distributes power to the front wheels FRW and FLW on the right and left sides when there is a difference in speed between them, for example, on a curve.

The engine ENG comprises a plurality of components such as an injector, a slot valve, an igniter, and intake and exhaust valves (these components are not shown). The injector is a fuel injecting valve which controls fuel to be injected into the cylinder of the engine ENG. The throttle valve controls the amount of air to be supplied to the cylinder of the engine ENG. The igniter is used to cause a mixture in the cylinder to burn. The intake and exhaust valves are open/close valves disposed for inhaling and exhaustion of the cylinder of the engine ENG.

The motors MG1 and MG2 are three-phase AC motors, that is, permanent magnet motors.

Three-phase AC inductive motors, reluctance motors, and the like can be used as the motors MG1 and MG2.

The motor MG1 and MG2 each include a rotor, which rotates, and a stator, which generates a rotating magnetic field.

The rotor is formed by embedding a plurality of permanent magnets in an iron core or by disposing a plurality of permanent magnets on the outer periphery of the iron core. The stator is formed by winding a copper wire around an electromagnet plate.

When three-phase current flows in the winding of the stator, a rotating magnetic field is generated. Torque generated on the rotor causes the motors MG1 and MG2 to rotate.

The inverter INV controls power to the motors MG1 and MG2 by switching the power semiconductor module. In brief, to control the motors MG1 and MG2, the inverter INV connects the high-voltage battery BAT, which is a DC power supply, to the motors MG1 and MG2 or disconnects the power supply. Since, in this embodiment, the motors MG1 and MG2 are three-phase AC motors, three-phase AC voltages are generated by prolonging and shortening a switching interval at which the power supply is turned on or off so as to control forces that drive the motors MG1 and MG2 (this type of called is called pulse-width modulation (PWM) control).

The inverter INV comprises a condenser module CM for supplying electric power for an instant during a switchover, a power semiconductor module PMU that causes switching, a driving circuit unit DCU for controlling the switching of the power module, and motor control unit MCU for determining a switching interval.

Since the inverter INV in this embodiment includes the power semiconductor module superior in heat dissipation, the INV has high reliability.

According to the embodiment described above, a power module that has low thermal resistance and requires less mounting space due to the use of less semiconductor chips can be provided, and thereby a smaller inverter INV can also be provided. Accordingly, a compact, highly reliable motor driving system mounted on a hybrid electric vehicle can be provided at a low cost.

What is claimed is:

1. A power semiconductor module that has a silicon nitride insulated substrate, a metal circuit board made of Cu or a Cu alloy, which is disposed on one surface of the silicon nitride insulated substrate, a semiconductor chip mounted on the metal circuit board, and a heat dissipating plate made of Cu or a Cu alloy, which is disposed on another surface of the silicon nitride insulated substrate, the power semiconductor module comprising a carbon fiber-metal composite made of carbon fiber and Cu or a Cu alloy between the silicon nitride insulated substrate and the metal circuit board, a thermal conductivity of the carbon fiber-metal composite in a direction in which carbon fiber of the carbon fiber-metal composite is oriented being 400 W/m·k or more.

2. The power semiconductor module according to claim 1, wherein:
the metal circuit board and the semiconductor chip are mutually bonded with Ag powder or an Ag sheet bonding material; and
a heat conductivity of a resulting bonding layer is 80 W/m·k or more but 400 W/m·k or less.

3. The power semiconductor module according to claim 1, wherein the thickness of the carbon fiber-metal composite is within a range of 0.2 to 5 mm.

4. The power semiconductor module according to claim 1, further comprising a surface layer made of Ni or Cu on a surface of the carbon fiber-metal composite, the thickness of the surface layer being within a range of 0.5 to 20 μm.

5. The power semiconductor module according to claim 1, wherein the carbon fiber-metal composite and the metal circuit are mutually brazed with an Ag—Cu—In filler metallic brazing material.

6. The power semiconductor module according to claim 1, wherein:
the carbon-fiber composite and the silicon nitride insulated substrate are mutually brazed with an Ag—Cu—In—Ti filler metallic brazing material; and
the silicon nitride insulated substrate and the heat dissipating plate is mutually brazed with an Ag—Cu—In—Ti filler metallic brazing material.

7. The power semiconductor module according to claim 1, wherein a saturated thermal resistance (Rj-w) is 0.15° C./W or less.

8. The power semiconductor module according to claim 1, further comprising a direct cooling mechanism immediately below the heat dissipating plate so as to bring the heat dissipating plate into contact with coolant; wherein:
a flow rate of the coolant is 5 liters/minute or more but 15 liters/minute or less; and
a water pressure is within a range of 5 to 50 kPa.

9. The power semiconductor module according to claim 1, wherein:
an operation current of the semiconductor chip is 300 A or more; and
an operation voltage is 300 V or more.

10. A vehicle-mounted inverter that uses the power semiconductor module according to claim 1.

11. A method of manufacturing a power semiconductor module that has a silicon nitride insulated substrate, a metal circuit board made of Cu or a Cu alloy, which is bonded to one surface of the silicon nitride insulated substrate through a carbon fiber-metal composite, a semiconductor chip mounted on the metal circuit board, and a heat dissipating plate made of Cu or a Cu alloy, which is disposed on another surface of the silicon nitride insulated substrate, the method comprising the steps of:
disposing an Ag—Cu—In filler metallic brazing material layer between the metal circuit board and the carbon fiber-metal composite;
disposing Ag—Cu—In—Ti filler metallic brazing material layers between the carbon fiber-metal composite and the silicon nitride insulated substrate and between the silicon nitride insulated substrate and the heat dissipating plate; and
simultaneously bonding the metal circuit board, the carbon fiber-metal composite, the silicon nitride insulated substrate, and the heat dissipating plate.

12. The method according to claim 11, wherein the carbon fiber-metal composite is made of carbon fiber and Cu or a Cu alloy, a thermal conductivity in a direction in which the carbon fiber is oriented being 400 W/m·k or more.

13. The method according to claim 11, wherein the step of simultaneously bonding the metal circuit board, the carbon fiber-metal composite, the silicon nitride insulated substrate, and the heat dissipating plate is carried out at temperatures from 600° C. to 800° C.
